(19) United States
(12) Patent Application Publication
(10) Pub. No.: US 2004/0251495 A1
(43) Pub. Date: Dec. 16, 2004

(54) Semiconductor device and manufacturing method of the same

(76) Inventors: Tetsuya Ikuta, Kawasaki (JP); Naoki Awaji, Kawasaki (JP); Mitsuaki Hori, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(21) Appl. No.: 10/809,809

(22) Filed: Mar. 26, 2004

(30) Foreign Application Priority Data
Mar. 26, 2003 (JP) 2003-085800
Aug. 27, 2003 (JP) 2003-303270
Mar. 5, 2004 (JP) 2004-062952

(51) Int. Cl. H01L 31/062

(52) U.S. Cl. 257/336

(57) ABSTRACT

A SiO₂ film is formed as a thermal oxide film on a surface of a Si substrate. Next, the SiO₂ film is heat-treated under a nitridation gas atmosphere to be changed to a SION film. As a result, a tensile stress toward a SiON film side acts on atoms existing on a surface layer of the Si substrate to cause distortion, so that the interatomic distance of the Si atoms in the Si substrate becomes longer. An amount of the distortion can be measured by, for example, an X-ray CTR scattering method. Next, a SiN film is formed on the SiON film by a CVD method or the like. The magnitude of the tensile stress acting on the Si substrate differs depending on the thickness of the SiN film. This method improves carrier mobility owing to the displacement of the Si atoms, so that sufficient carrier mobility can be obtained even when nitrogen concentration near an interface between the SiON film and the Si substrate is high.

### CROSS-REFERENCE TO RELATED APPLICATIONS

This application is based upon and claims the benefit of priority from the prior Japanese Patent Application Nos. 2003-085800 filed on Mar. 26, 2003, 2003-303270 filed on Aug. 27, 2003, and 2004-062952 filed on Mar. 5, 2004, the entire contents of which are incorporated herein by reference.

### BACKGROUND OF THE INVENTION

1. Field of the Invention

The present invention relates to a semiconductor device and a manufacturing method of the same capable of suppressing the increase in boron penetration and in gate leak current that tend to occur as semiconductor devices are scaled down.

2. Description of the Related Art

As semiconductor devices are scaled down, a thickness of a gate oxide film is also becoming reduced in accordance with a scaling law. However, use of such a very thin gate oxide film causes problems of increase in gate leak current density and variation in threshold value voltage due to boron diffusion from a gate electrode to a channel through the gate insulation film. The latter phenomenon of the boron diffusion is also called boron penetration. An effective method to prevent the boron penetration is nitriding or oxynitriding a gate insulation film (a silicon oxide film) so that the gate insulation film contains nitrogen. As a method for the gate insulation film to contain nitrogen, available are a method of forming the film using NO and a method of plasma nitridation.

In a conventional oxynitridation method, nitrogen concentration is at its peak near an interface between a silicon substrate and a silicon oxide film. This is because molecules contributing to nitridation diffuse in the silicon oxide film to react near the interface with the silicon substrate.

A required nitrogen concentration for sufficiently suppressing the boron penetration from a gate electrode is about 1% or higher, though depending on heat treatment conditions after the gate electrode is formed. However, if the gate insulation film in which nitrogen concentration is at its peak near the interface between the silicon substrate and the silicon oxide film contains more than about 1% nitrogen, there arises a problem of decrease in carrier mobility as a secondary effect.

Therefore, a preferable concentration profile for effectively suppressing the boron penetration while suppressing the decrease in carrier mobility is such that nitrogen concentration is at its peak near an interface between the gate insulation film and the gate electrode.

On the other hand, the most preferable concentration profile for suppressing characteristic deterioration of a device due to withstand voltage and hot carriers as well as suppressing the boron penetration is such that nitrogen concentration is at its peak at an upper end and a lower end of the gate insulation film. However, if nitrogen concentration near the interface between the silicon substrate and the gate insulation film is too high, carrier mobility decreases as described above. Therefore, the concentration profile such that nitrogen concentration is 1% or lower near the interface with the silicon substrate and 1% or higher near the interface with the gate electrode is considered to be the most preferable.

An example of a method for obtaining the concentration profile such that nitrogen concentration is at its peak near the interface between the gate insulation film and the gate electrode is depositing a silicon nitride film by chemical vapor deposition (CVD) after a surface of a silicon substrate is oxidized. Further, there is also a method of annealing a silicon oxide film with a thickness of about 2 nm to about 3 nm in an ammonia atmosphere with the aim of densely depositing a silicon nitride film to introduce nitrogen of 1% or lower to the vicinity of the interface with a silicon substrate.

Another example is a method of plasma-nitridation of a silicon oxide film.

However, any of the conventional methods can neither sufficiently improve carrier mobility nor reduce leak current.

Prior arts are disclosed in Japanese Patent Application Laid-open No. Hei 6-232408 and Japanese Patent Application Laid-open No. Hei 5-283679.

### SUMMARY OF THE INVENTION

It is an object of the present invention to provide a semiconductor device and a manufacturing method of the same capable of sufficiently improving carrier mobility and reducing leak current.

It has been conventionally considered preferable that nitrogen concentration in a gate insulation film is 1% or lower near an interface with a silicon substrate. For this reason, ammonia annealing under the condition causing nitrogen concentration to exceed 1% near the interface with the silicon substrate has been avoided.

However, as a result of assiduous studies, the inventors of the present invention have found out that, when ammonia annealing is conducted under the condition causing nitrogen concentration to exceed 1% near an interface with a silicon substrate, Si atoms existing on a surface of the Si substrate are displaced in a direction of a gate insulation film, resulting in improved carrier mobility.

The inventors of the present invention have come up with various forms of invention as described below.

A semiconductor device according to the present invention comprises: a silicon substrate; a gate insulation film formed over the silicon substrate; and a gate electrode formed over the gate insulation film. Silicon atoms on a surface of the silicon substrate are displaced toward the gate insulation film side.

In a manufacturing method of a semiconductor device according to the present invention, after a gate insulation film is formed over a silicon substrate, a gate electrode is formed over the gate insulation film. In a gate insulation film being formed, a silicon oxide film is formed over the silicon substrate, and then, nitrogen is introduced into the silicon oxide film and silicon atoms on a surface of the silicon substrate is displaced toward the gate insulation film side.

### BRIEF DESCRIPTION OF THE DRAWINGS

FIG. 1A to FIG. 1F are cross sectional views showing a manufacturing method of a semiconductor device according to a first embodiment of the present invention in the order of processes;

FIG. 2, which relates to the first embodiment, is a graph showing a correlation between gate voltage and trans-conductance;

FIG. 3, which relates to the first embodiment, is a graph showing a correlation between inversion capacitance equivalent thickness and gate leak current;

FIG. 4, which relates to the first embodiment, is a graph showing a correlation between annealing temperature and displacement amount of atoms;

FIG. 5 is a graph showing a correlation of gate leak current and the value of Gmₘₐₓ×T_{eff} to displacement amount in an n-channel MOS transistor;

FIG. 6 is a cross sectional view showing a manufacturing method of a semiconductor device according to a second embodiment of the present invention;

FIG. 7, which relates to the second embodiment, is a graph showing a correlation between gate voltage and trans-conductance;

FIG. 8, which relates to the second embodiment, is a graph showing a correlation between inversion capacitance equivalent thickness and gate leak current;

FIG. 9, which relates to the second embodiment, is a graph showing a correlation between annealing condition and the displacement amount of atoms;

FIG. 10A to FIG. 10C are cross sectional views showing a manufacturing method of a semiconductor device according to a third embodiment of the present invention in the order of processes;

FIG. 11, which relates to the third embodiment, is a graph showing a correlation between a structure of a gate insulation film and a displacement amount of atoms;

FIG. 12A to FIG. 12F are cross sectional views showing a manufacturing method of a semiconductor device according to a fourth embodiment of the present invention in the order of processes;

FIG. 13A to FIG. 13C are cross sectional views showing a manufacturing method of a semiconductor device according to a fifth embodiment of the present invention in the order of processes;

FIG. 14A and FIG. 14B, which relate to the fourth embodiment and the fifth embodiment, are graphs showing a correlation between gate voltage and carrier mobility;

FIG. 15 is a graph showing a correlation between a displacement amount of atoms and maximum carrier mobility;

FIG. 16 is a graph showing a correlation between a gate insulation film forming method and a displacement amount of atoms;

FIG. 17, which relates to the first embodiment, is a graph showing a correlation between annealing temperature and variation in threshold value;

FIG. 18 is a graph showing a correlation between a displacement amount of Si atoms and variation in threshold value; and

FIG. 19, which relates to the second embodiment, is a graph showing a correlation between annealing temperature and variation in threshold value.

### DETAILED DESCRIPTION OF THE PREFERRED EMBODIMENTS

Hereinafter, embodiments of the present invention will be concretely explained with reference to the attached drawings. The structure of a semiconductor device will be explained along with a manufacturing method thereof for convenience' sake.

First Embodiment

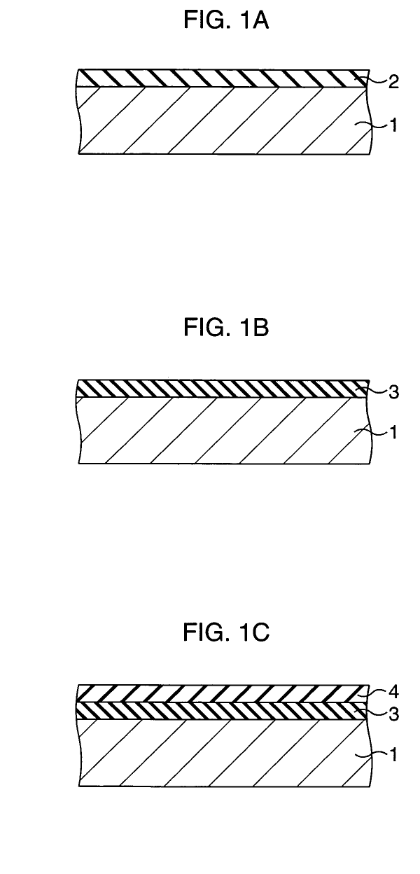

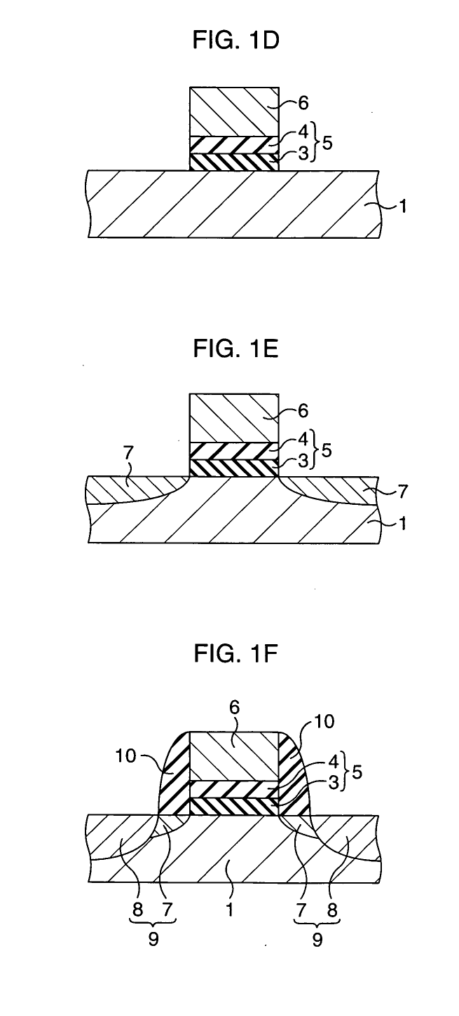

To begin with, a first embodiment of the present invention will be explained. FIG. 1A to FIG. 1F are cross sectional views showing a manufacturing method of a semiconductor device according to the first embodiment of the present invention in the order of processes. In the first embodiment, a semiconductor device having an n-channel MOS transistor is manufactured.

In the first embodiment, a semiconductor substrate, for example, a Si substrate 1 is wet-cleaned first, and thereafter, a SiO₂ film 2 is formed as a thermal oxide film as shown in FIG. 1A by furnace annealing or heat treatment using a RTP (Rapid Thermal Processing) apparatus. In more detail, in this embodiment, the SiO₂ film 2 with a thickness of 1.5 nm or less, for example, about 1 nm is formed by dry oxidization at 850° C.

Next, the SiO₂ film 2 is heat-treated under a nitridation gas atmosphere to be changed to a SION film 3 as shown in FIG. 1B. In more detail, in this embodiment, the pressure inside a chamber is controlled to 800 Pa while an NH₃ gas is supplied thereto at a flow rate of 2 liter/min., and ten-minute ammonia annealing (first heat treatment) is conducted at 850° C. As a result, a tensile stress toward a SiON film 3 side acts on atoms existing on a surface layer of the Si substrate 1 to cause distortion, so that a interatomic distance of Si atoms in the Si substrate 1 becomes longer. The direction and amount of the distortion (displacement) can be measured by, for example, an X-ray CTR (Crystal Truncation Rod) scattering method. Incidentally, plasma nitridation of the SiO₂ film 2 reduces the interatomic distance since a compressive stress from the SiON film 3 side acts, contrary to the above heat treatment. Further, as the first heat treatment, nitrogen monoxide annealing may be conducted.

Next, a SiN film 4 is formed on the SION film 3 by a CVD method or the like. In more detail, in this embodiment, the SiN film 4 with a thickness of about 0.2 nm is formed under a temperature of 650° C. using dichlorosilane and NH₃ as source gases. A magnitude of the tensile stress acting on the Si substrate 1 differs depending also on a thickness of the SiN film 4. In other words, control over the thickness of the SiN film 4 makes it possible to control the magnitude of the tensile stress and the accompanying distortion.

Processes of forming these insulation films may be conducted using a plurality of chambers, but are preferably conducted continuously using a single chamber without allowing the air to enter the inside of the chamber.

After the SiN film 4 is formed, a gate electrode 6 is formed on a gate insulation film 5 including the SION film 3 and the SiN film 4 as shown in FIG. 1D.

Next, as shown in FIG. 1E, n-type impurities are ion-implanted, using the gate electrode 6 as a mask, so that low-concentration impurity diffusion layers 7 are formed on a surface of the Si substrate 1.

Next, as shown in FIG. 1F, sidewall insulation films 10 are formed on side portions of the gate electrode 6, and n-type impurities are ion-implanted, with the gate electrode 6 and the sidewall insulation films 10 serving as a mask, so that high-concentration impurity diffusion layers 8 are formed on the surface of the Si substrate 1. The low-concentration impurity diffusion layers 7 and the high-concentration impurity diffusion layers 8 constitute source-drain regions 9. Thus, the n-channel MOS transistor is formed.

Then, interlayer insulation films, wirings, and so on are formed to complete the semiconductor device.

According to the first embodiment as described above, carrier mobility is improved owing to the displacement of the Si atoms on the surface of the Si substrate 1. Consequently, even when the ammonia annealing increases nitrogen concentration near the interface between the SiON film 3 and the Si substrate 1, sufficient carrier mobility is obtained. Further, the increase in nitrogen concentration prevents the easy occurrence of boron penetration and reduces gate leak current.

Here, the effects of the first embodiment will be explained.

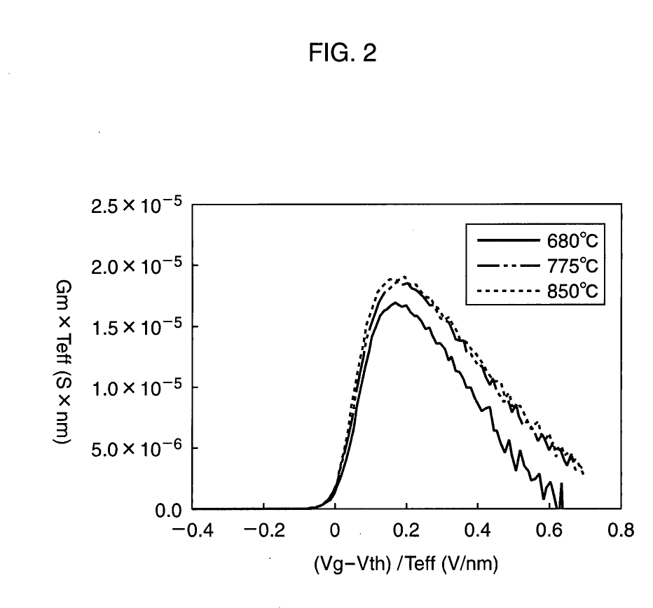

The inventors of the present invention made an n-channel MOS transistor as an example in the same manner as that in the first embodiment, and further made n-channel MOS transistors as other examples under the conditions that the temperature of the ammonia annealing of the SiO₂ film 2 is set to 680° C. and 775° C., respectively. Note that the conditions except the temperature of the ammonia annealing were set to be uniform in making these three kinds of n-channel MOS transistors. Then, trans-conductance (Gm) and gate voltage (Vg) were measured in these three kinds of MOS transistors. The result corrected with inversion capacitance equivalent thickness (T_{eff}) is shown in FIG. 2.

As shown in FIG. 2, the higher the annealing temperature was, the higher was the value of Gm×T_{eff}, which is one of indexes representing carrier mobility, though the higher was the nitrogen concentration in the gate insulation film 5. At the annealing temperature of 680° C., it may be thought that substantially no tensile stress acts on the Si substrate 1. Therefore, the annealing temperature is preferably set to 775° C. or higher.

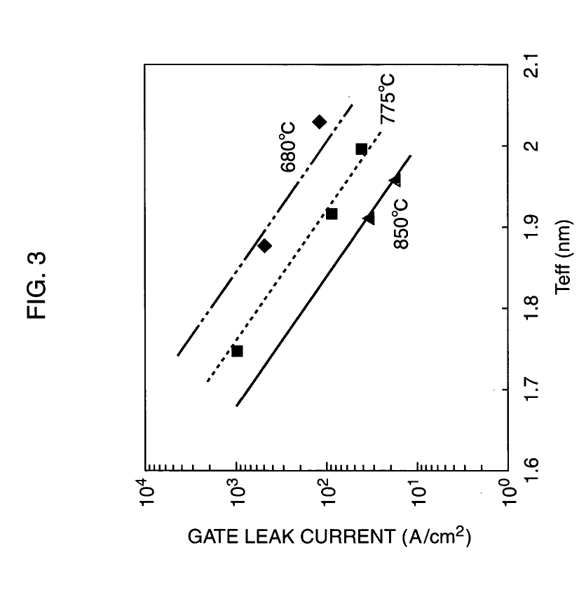

The inventors of the present invention measured gate leak current in the aforesaid three kinds of n-channel MOS transistors when gate voltage was 1 V. The result is shown in FIG. 3.

As shown in FIG. 3, the higher the annealing temperature was, the lower the gate leak current was. This is thought to result from the fact that nitrogen concentration increases in accordance with the increase in the annealing temperature.

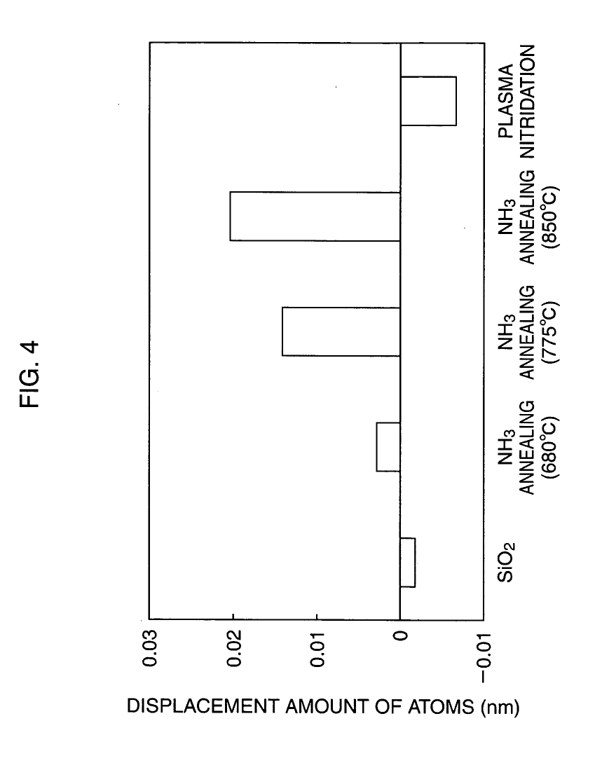

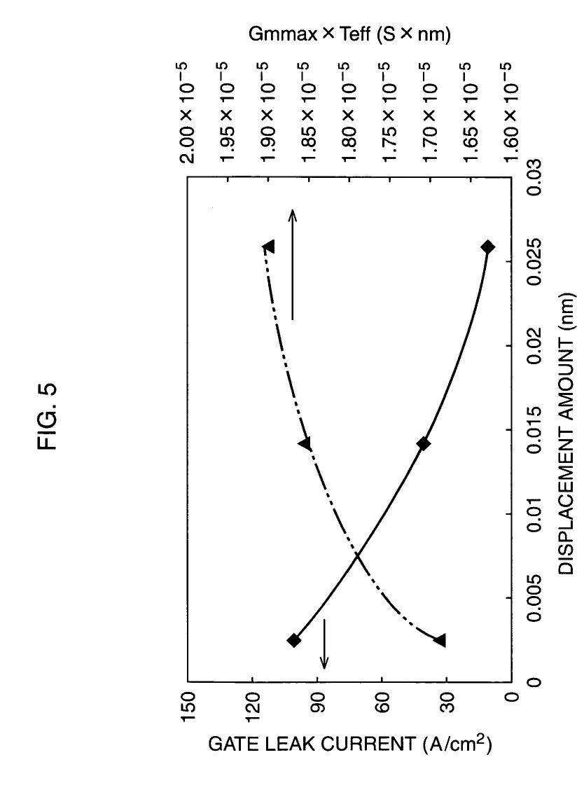

The inventors of the present invention measured the displacement amount of Si atoms on the surface of the Si substrate 1 by an X-ray CTR scattering method in the aforesaid three kinds of n-channel MOS transistors. Further, as comparisons, the displacement amount when plasma nitridation was conducted and the displacement when the SiO₂ film was neither ammonia-annealed nor plasma-nitrided were also measured. These results are shown in FIG. 4. The positive value on the vertical axis of the graph shown in FIG. 5 represents the displacement accompanying the tensile stress, and the negative value represents the displacement accompanying the compressive stress.

As shown in FIG. 4, when the ammonia annealing was conducted, distortion accompanying the tensile stress occurred and the displacement of Si atoms in a direction causing the increase in the interatomic distance occurred. On the other hand, when the plasma nitridation was conducted and when the nitridation was not conducted, distortion accompanying the compressive stress occurred, and the displacement of Si atoms in a direction causing the reduction in the interatomic distance occurred.

FIG. 5 is a graph showing a correlation of gate leak current and the value of Gmₘₐₓ×T_{eff} to displacement amount in an n-channel MOS transistor. A solid line in FIG. 5 represents a correlation between the displacement amount and the gate leak current (NMOS), and a chain double-dashed line represents a correlation between the displacement amount and the value of Gmₘₐₓ×T_{eff} (NMOS).

As shown in FIG. 5, good results are obtained in the n-channel MOS transistor especially when the displacement amount of the Si atoms is 0.0075 nm or more.

It should be noted that such a high dielectric constant film as an HfO₂ film, an oxide film of Ta, Zr, La, Pr or the like may be used instead of the SiN film 4.

Second Embodiment

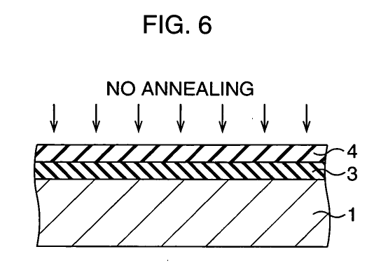

Next, a second embodiment of the present invention will be explained. In the second embodiment, processes up to the formation of a SiN film 4 (or a high dielectric constant film) are first conducted similarly to the first embodiment. Then, after the SiN film 4 is formed, annealing (second heat treatment) at a higher temperature than that of the film deposition temperature of the SiN film 4 is conducted to form a gate insulation film 5. In more detail, in the present embodiment, a pressure in a chamber is controlled to 13.3 kPa and 20-minute NO annealing is conducted at 850° C., as shown in FIG. 6. As a result, a tensile stress toward a SiON film 3 side acts again on atoms existing on a surface layer of a Si substrate 1 to cause distortion, so that a interatomic distance of Si atoms in the Si substrate 1 becomes still longer. Thereafter, processes on and after the formation of a gate electrode 6 are conducted similarly to the first embodiment to complete a semiconductor device.

According to the second embodiment as described above, carrier mobility is further improved to enable higher speed operation and to reduce gate leak current.

Incidentally, the atmosphere of the annealing conducted after the formation of the SiN film 4 is not limited to a specific one. It may be, for example, an N₂ atmosphere, an N₂O atmosphere, an O₂ atmosphere, an atmosphere of mixture of these gases, or the like other than the NO atmosphere. However, since the highest effect is obtained in the NO atmosphere as described later, it is preferable to use the NO atmosphere.

Here, the effects of the second embodiment will be explained.

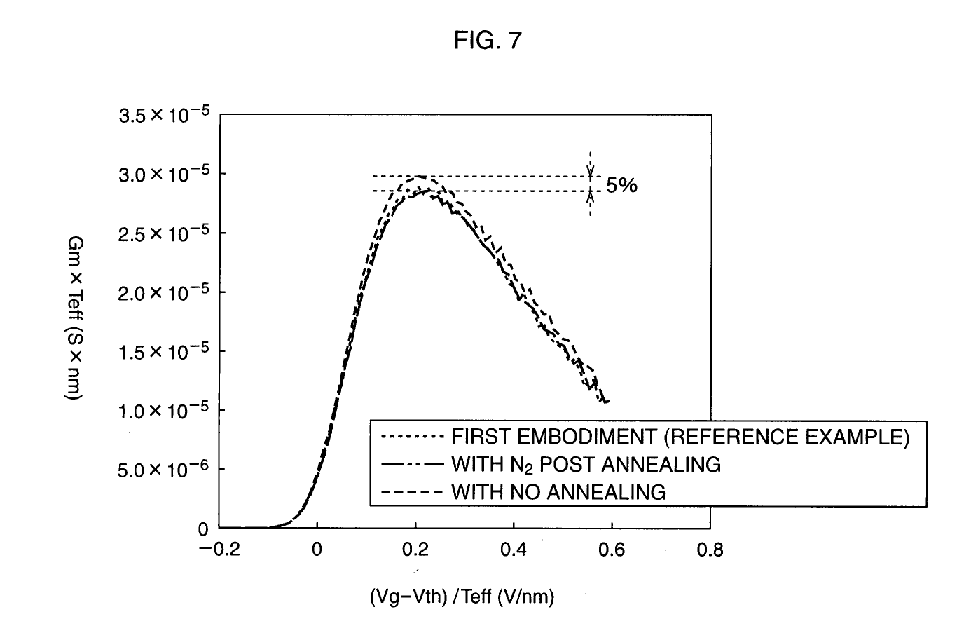

The inventors of the present invention made as an example an n-channel MOS transistor in the same manner as that in the second embodiment, and further made as another example an n-channel MOS transistor under the condition that the atmosphere of the annealing after the formation of the SiN film 4 (post-annealing) was set to an N₂ atmosphere. In addition, an n-channel MOS transistor was made as a reference example (still another example) in the same manner as that in the first embodiment (the temperature of the ammonia annealing after the formation of the SiO₂ film 2: 850° C.). Note that the conditions except the post-annealing condition were uniformly set in making the three kinds of n-channel MOS transistors. Then, trans-conductance (Gm) and gate voltage (Vg) were measured in these three kinds of MOS transistors. The results corrected with inversion capacitance equivalent thickness (T_{eff}) are shown in FIG. 7.

As shown in FIG. 7, when the annealing was conducted in the NO atmosphere, the value of Gm×T_{eff} was about 5% higher than the value obtained in the reference example (first embodiment).

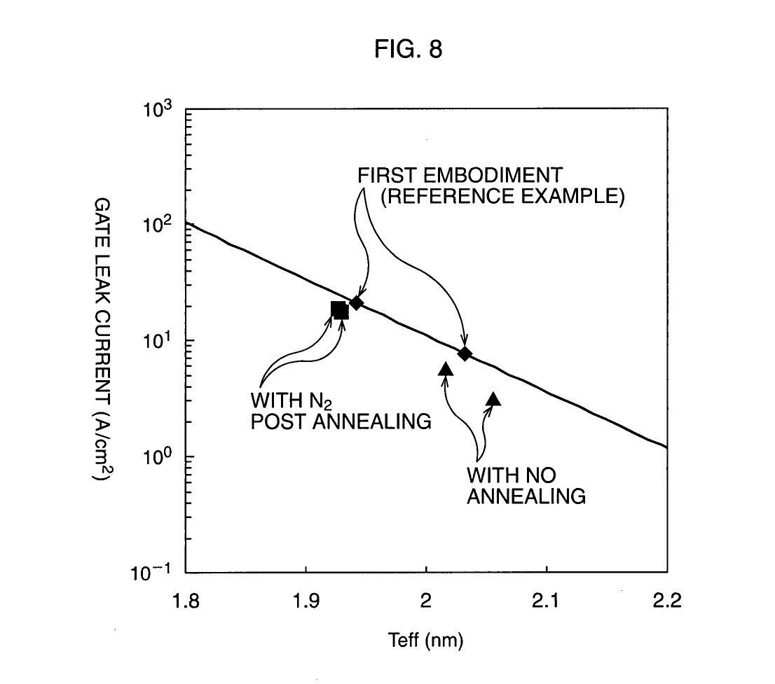

The inventors of the present invention further measured gate leak current in the aforesaid three kinds of MOS transistors when gate voltage is 1 V. The result is shown in FIG. 8.

As shown in FIG. 8, the application of the post-annealing resulted in the gate leak current lower than that of the reference example (first embodiment), regardless of the kind of the annealing.

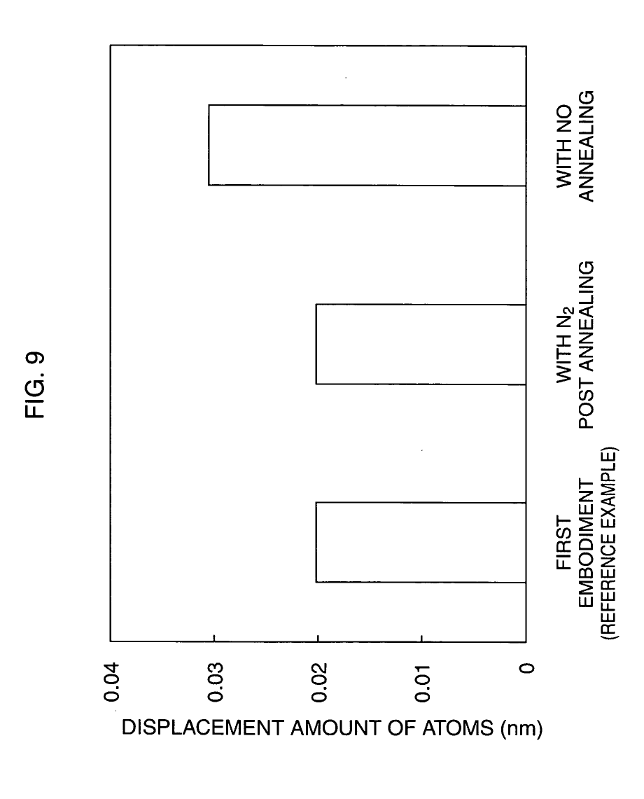

The inventors of the present invention further measured the displacement amount of Si atoms on a surface of a Si substrate 1 by an X-ray CTR scattering method in the aforesaid three kinds of n-channel MOS transistors. The result is shown in FIG. 9.

As shown in FIG. 9, in any of the examples, the displacement amount of the Si atoms was 0.02 nm or more, and when the NO annealing was conducted after the formation of the SiN film 4, distortion accompanying the tensile stress was larger than that in any other examples.

It is seen from the comparison between FIG. 7 to FIG. 9 and FIG. 2 to FIG. 4 that the results of the transistor (reference example) made in the same manner as that in the first embodiment are slightly different from each other. This is because a transistor producing method used in the experiment whose result is shown in FIG. 7 to FIG. 9 and a transistor producing method used in the experiment whose result is shown in FIG. 2 to FIG. 4 are slightly different from each other. However, this slight difference is so insignificant that it does not give any influence to the operation and effect of the present invention.

Third Embodiment

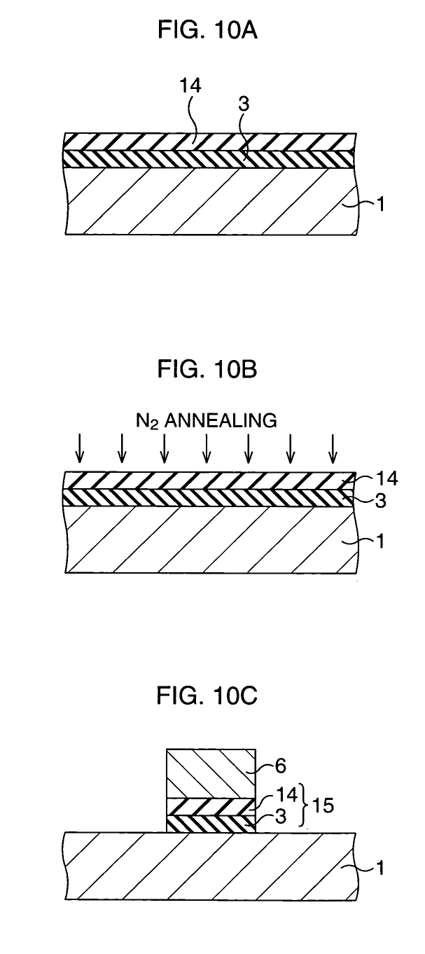

Next, a third embodiment of the present invention will be explained. In the third embodiment, the structure of a gate insulation film is made different from those of the first and second embodiments. FIG. 10A to FIG. 10C are cross sectional views showing a manufacturing method of a semiconductor device according to the third embodiment of the present invention in the order of processes.

In the third embodiment, processes up to the formation of a SiON film 3 are first conducted as shown in FIG. 10A similarly to the first and second embodiments. Next, an HfO₂ film 14 as a high dielectric constant film is formed instead of the SiN film 4 on the SION film 3. The HfO₂ film 14 is formed by, for example, ALD (Atomic Layered Deposition). A thickness thereof is, for example, about 3 nm. Next, as shown in FIG. 10B, N₂ annealing as a second heat treatment is conducted at a higher temperature than the film deposition temperature of the HfO₂ film 14, similarly to the second embodiment. Thereafter, as shown in FIG. 10C, processes on and after the formation of a gate electrode 6 are conducted similarly to the first and second embodiments to complete the semiconductor device.

In the third embodiment as described above, it is also possible to displace Si atoms existing on a surface layer of a Si substrate 1 toward a gate insulation film 15 side in an n-channel MOS transistor. Therefore, even when ammonia annealing increases nitrogen concentration near an interface between the SiON film 3 and the Si substrate 1, sufficient carrier mobility is obtained.

Here, the effects of the third embodiment will be explained.

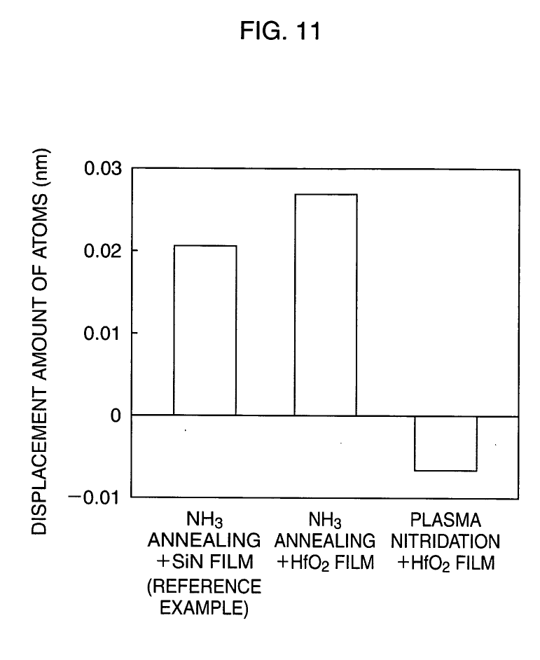

The inventors of the present invention made an n-channel MOS transistor as an example in the same manner as that in the third embodiment. Then, the displacement amount of Si atoms on a surface of a Si substrate 1 was measured by an X-ray CTR scattering method. Further, as comparison, measurement was also made of the displacement amount when an HfO₂ film was formed after plasma nitridation was conducted. These results are shown in FIG. 11. The positive value on the vertical axis of the graph shown in FIG. 11 represents the displacement accompanying a tensile stress, and the negative value represents the displacement accompanying a compressive stress. FIG. 11 also shows the result of “with N₂ post-annealing” shown in FIG. 9 as a reference example.

As shown in FIG. 11, the sample in which the HfO₂ film 14 is formed shows a larger displacement amount of atoms accompanying the tensile stress than that of the reference example in which the SiN film 4 is formed.

Incidentally, in the third embodiment, the N₂ annealing is conducted as the post-annealing, but NO annealing may be conducted instead. Further, as in the first embodiment, the post-annealing itself need not be conducted. Further, the kind of the high dielectric constant film is not limited. For example, an oxide film of Ta, Zr, La, Pr or the like is also usable.

Fourth Embodiment

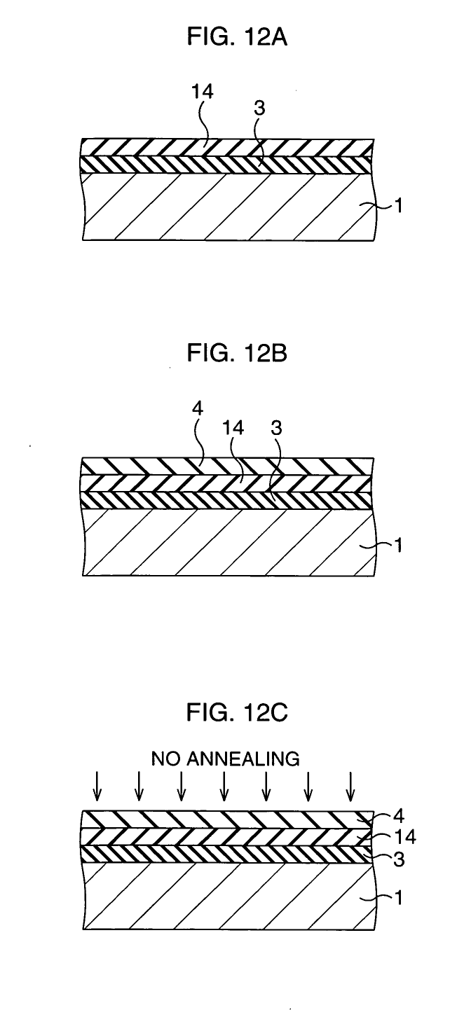

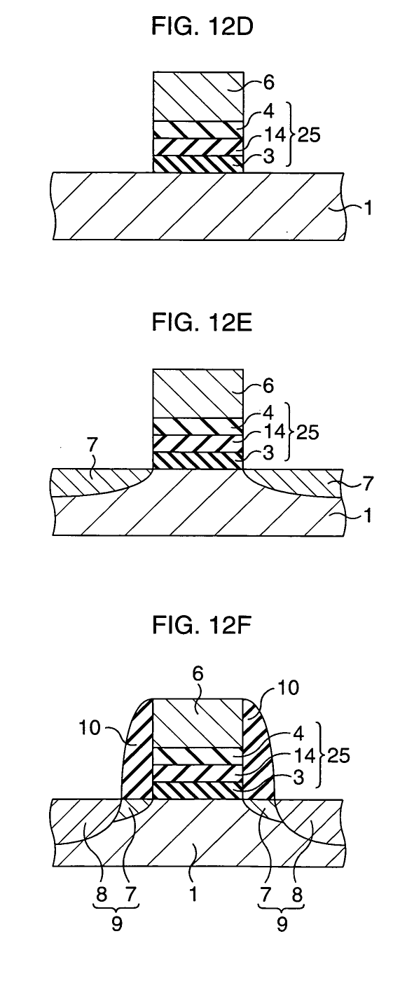

Next, a fourth embodiment of the present invention will be explained. The fourth embodiment is the combination of the second embodiment and the third embodiment. FIG. 12A to FIG. 12F are cross sectional views showing a manufacturing method of a semiconductor device according to the fourth embodiment of the present invention in the order of processes.

In the fourth embodiment, processes up to the formation of an HfO₂ film 14 are first conducted as shown in FIG. 12A, similarly to the third embodiment. Next, as shown in FIG. 12B, a SiN film 4 is formed on the HfO₂ film 14 similarly to the second embodiment. Next, as shown in FIG. 12C, NO annealing is conducted similarly to the second embodiment. Thereafter, as shown in FIG. 12D to FIG. 12F, processes on and after the formation of a gate electrode 6 are conducted similarly to the first to third embodiments to complete the semiconductor device. The NO annealing may be conducted before the SiN film 4 being formed.

According to the fourth embodiment as described above, the combination of the SiN film 4 and the HfO₂ film 14 enables further increase in physical film thickness while a high dielectric constant is being maintained. This enables more effective reduction in leak current.

Fifth Embodiment

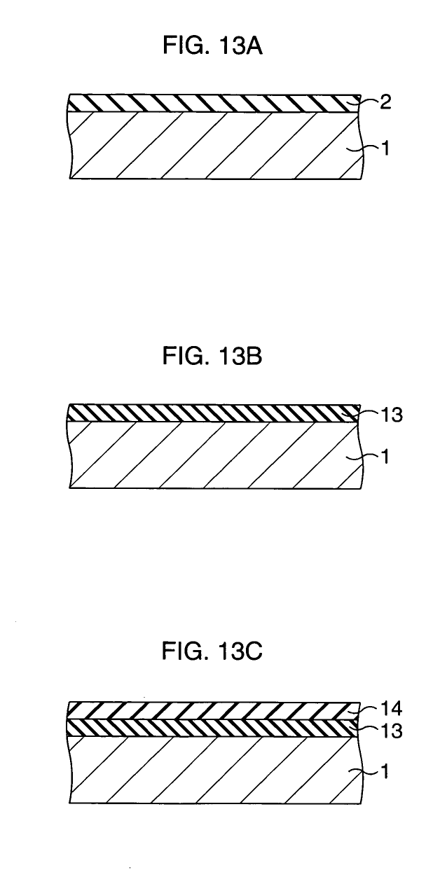

Next, a fifth embodiment of the present invention will be explained. In the fifth embodiment, an n-channel MOS transistor is formed by the method according to the fourth embodiment and a p-channel MOS transistor is formed in parallel therewith, so that a semiconductor device having the n-channel MOS transistor and the p-channel MOS transistor is manufactured. FIG. 13A to FIG. 13C are cross sectional views showing a manufacturing method of the semiconductor device according to the fifth embodiment of the present invention. Note that FIG. 13A to 13C only show a portion where the p-channel MOS transistor is formed.

In the fifth embodiment, a SiO₂ film 2 is first formed on a surface of a Si substrate 1 similarly to the first embodiment as shown in FIG. 13A.

Next, in a region in which the p-channel MOS transistor is to be formed, the SiO₂ film 2 is plasma-nitrided to be changed to a SiON film 13 as shown in FIG. 13B. Further, in a region where the n-channel MOS transistor is to be formed, heat treatment is conducted under a nitridation gas atmosphere similarly to the first to fourth embodiments, so that the SiO₂ film 2 is changed to a SiON film 3, as shown in FIG. 12A. As a result, in the region where the p-channel MOS transistor is to be formed, a compressive stress acts on atoms existing on a surface layer of the Si substrate 1 from a SiON film 13 side to cause distortion, so that the interatomic distance of Si atoms in the Si substrate 1 becomes shorter. On the other hand, in the region where the n-channel MOS transistor is to be formed, the interatomic distance of the Si atoms in the Si substrate becomes longer. Incidentally, in the plasma nitridation and thermal nitridation, selective processing is possible by, for example, using masks having openings formed only in the regions to which these processes are applied, respectively.

Next, as shown in FIG. 13C and FIG. 12A, an HfO₂ film 14 is formed on each of the SION films 3 and 13. Thereafter, similarly to the fourth embodiment, processes on and after the formation of a SiN film 4 are conducted to complete the semiconductor device. Note that p-type impurities are ion-implanted in the region where the p-channel MOS transistor is to be formed in forming impurity diffusion layers.

Thus, in the fifth embodiment, in forming the n-channel MOS transistor and the p-channel MOS transistor in parallel, the respective displacement directions of the Si atoms on the surface layer of the Si substrate 1 are made reverse to each other. As a result, it is possible to reduce leak current while achieving high mobility both in the n-channel MOS transistor and the p-channel MOS transistor.

Here, the effects of the fourth and fifth embodiments will be explained.

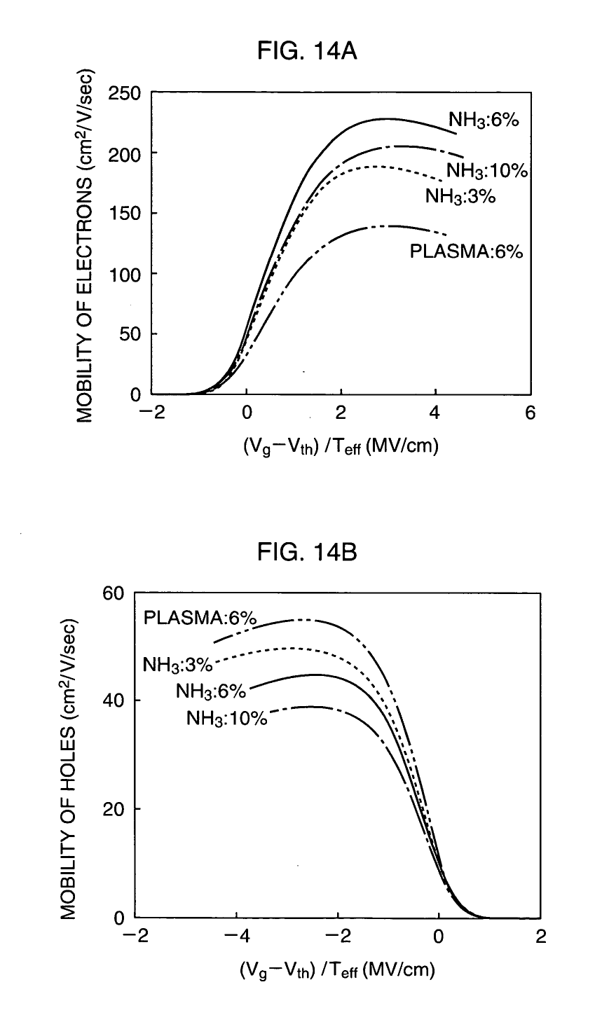

The inventors of the present invention thermally nitrided (NH₃ annealing) or plasma-nitrided SiO₂ films to make four kinds of n-channel MOS transistors and four kinds of p-channel MOS transistors. As a result, in the thermally nitrided samples, nitrogen concentration on an interface between a Si substrate and a SiON film was 3 at %, 6 at %, or 10 at % in both the n-channel MOS transistors and the p-channel MOS transistors. In the plasma-nitrided samples, nitrogen concentration on the interface was 6 at %. Then, carrier mobility and gate voltage (Vg) were measured in these four kinds of MOS transistors. This result corrected with inversion capacitance equivalent capacitance (T_{eff}) is shown in FIG. 14A and FIG. 14B. Note that electron mobility in the n-channel MOS transistors was measured as shown in FIG. 14A, and hole mobility in the p-channel MOS transistors was measured as shown in FIG. 14B.

Conventionally, it has been generally thought that mobility is decreased in accordance with the increase in interface nitrogen concentration. However, from the results shown in FIG. 14A and FIG. 14B, it cannot be said that mobility decreases even when the interface nitrogen concentration increases. On the other hand, it can be said that higher mobility is obtained in the n-channel MOS transistor when the thermal nitridation is conducted than when the plasma nitridation is conducted, as shown in FIG. 14A, while, in the p-channel MOS transistor, higher mobility is obtained when the plasma nitridation is conducted than when the thermal nitridation is conducted as shown in FIG. 14B.

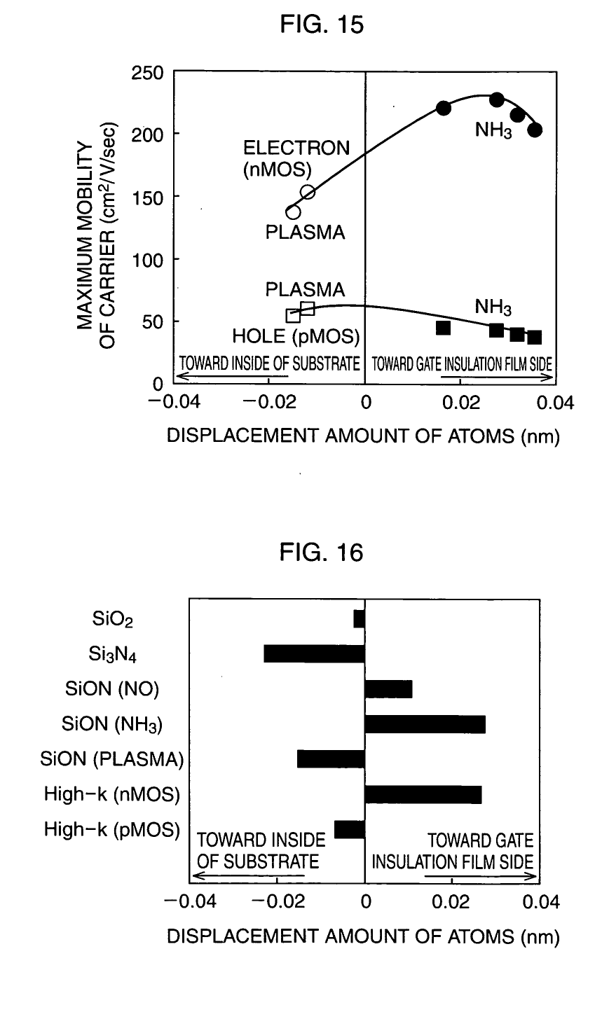

Under such circumstances, the inventors of the present invention further studied a correlation between a conductive type of a channel and a displacement amount of atoms. The following result was obtained from the studies. FIG. 15 is a graph showing a correlation between a displacement amount of atoms and maximum carrier mobility. In FIG. 15, a mark ● represents the maximum electron mobility in n-channel MOS transistors made with NH₃ annealing. A mark ◯ represents the maximum electron mobility in n-channel MOS transistors made with plasma-nitridation. Further, a mark ▪ represents the maximum hole mobility in p-channel MOS transistors made with NH₃ annealing. A mark □ represents the maximum hole mobility in p-channel MOS transistors made with plasma-nitridation was conducted.

As shown in FIG. 15, in the n-channel MOS transistors, the maximum electron mobility is the highest when the displacement of Si atoms existing on a surface layer of a Si substrate is about 0.025 nm toward a gate insulation film side. On the other hand, in the p-channel MOS transistors, the maximum hole mobility is the highest when the displacement of Si atoms existing on a surface layer of a Si substrate is about 0.005 nm toward the inner side of the substrate. It can be said from the result shown in FIG. 15 that the displacement amount of Si atoms toward a gate insulation film side is preferably 0.0075 nm or more, especially, 0.01 nm to 0.03 nm in n-channel MOS transistors, and the displacement amount of Si atoms toward the inner side of a substrate is preferably 0.01 nm or less in p-channel MOS transistors.

The inventors of the present invention further studied a correlation between a gate insulation film forming method and a displacement amount of atoms. The result is shown in FIG. 16.

As shown FIG. 16, when a gate insulation film is formed only of a SiO₂ film and when a SiN film (Si₃N₄ film) is simply formed to form a gate insulation film, the displacement direction of Si atoms existing on the surface of a Si substrate was toward the inner side of the substrate. On the other hand, when a SiO₂ film was subjected to NO annealing or NH₃ annealing to form a SiON film, and a SiN film is thereafter formed thereon to form a gate insulation film, the displacement direction of Si atoms was toward the gate insulation film side. Similarly, when a SiO₂ film was subjected to NH₃ annealing to form a SiON film, and an HfO₂ film and a SiN film were formed thereafter in sequence thereon to form a gate insulation film, the displacement direction of Si atoms was also toward the gate insulation film side. When a SiO₂ film was nitrided to form a SiON film, the displacement direction of Si atoms was also toward the inner side of the substrate if plasma nitridation was used and if an HfO₂ film and a SiN film were formed on the SiON film after plasma nitridation was conducted.

Incidentally, according to the first to third embodiments, it is also possible to form a p-channel MOS transistor in parallel to the formation of the n-channel MOS transistor. In this case, it is also preferable that atoms on the substrate surface layer are displaced toward the gate insulation film side in the n-channel MOS transistor and atoms on the substrate surface layer are displaced toward the inner side of the substrate in the p-channel MOS transistor.

Here, the result of measurement on variation in threshold value made by the inventor of the present invention will be explained.

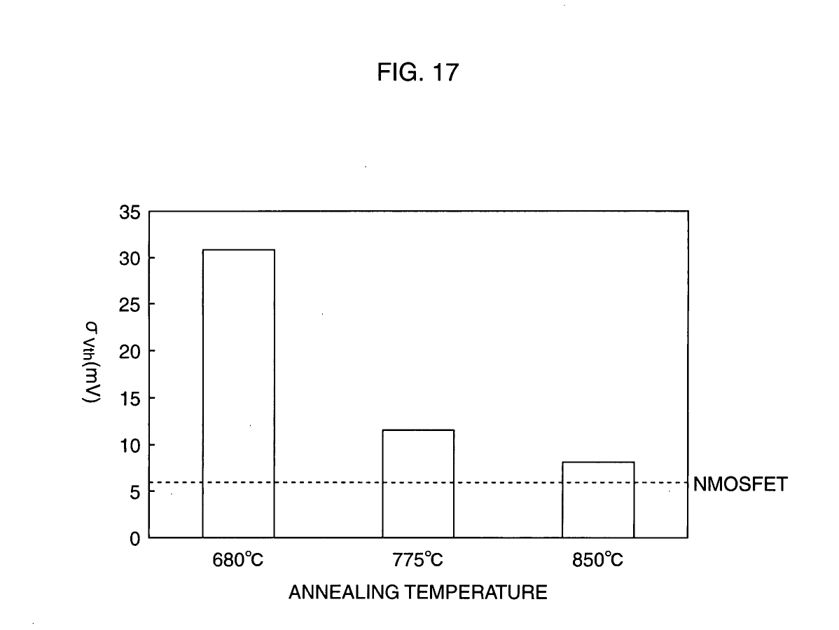

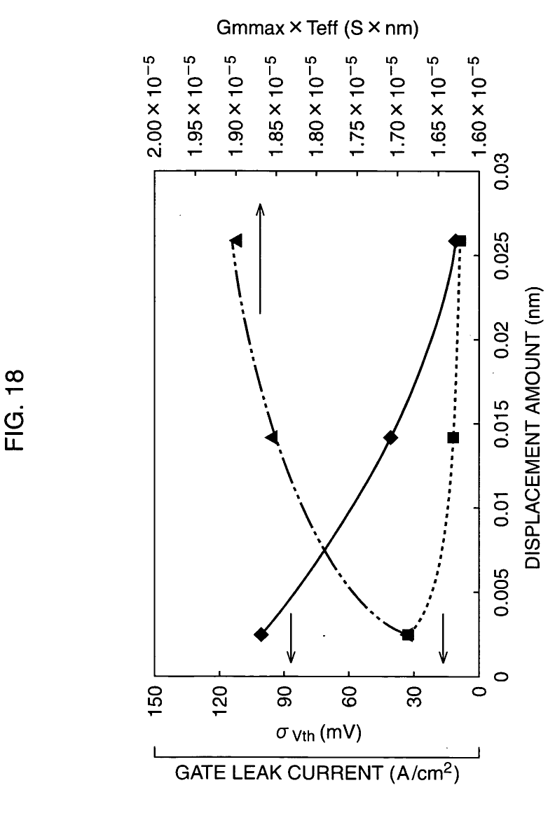

In this measurement, three kinds of p-channel MOS transistors were made by a method according to the first embodiment. Then, variation (σ_{Vth}) in threshold value voltage was measured in these transistors. Note that in making the three kinds of p-channel MOS transistors, ammonia annealing was conducted at the same annealing temperature as that for the three kinds of n-channel MOS transistors made for the measurement of trans-conductance (Gm) and gate voltage (Vg) which was made relating to the first embodiment. The result is shown in FIG. 17.

As shown in FIG. 17, the higher the annealing temperature was, the smaller the variation in threshold value voltage was. This indicates that boron penetration is suppressed. Note that the broken line in FIG. 17 represents the variation in threshold value voltage in the n-channel MOS transistor. In the n-channel MOS transistor, the influence given by the annealing temperature to the variation in threshold value voltage is small.

Further, the inventors of the present invention also studied a correlation between a displacement amount of Si atoms on the surface of a Si substrate 1 and variation (σᵥₜₕ) in threshold value voltage in a p-channel MOS transistor. The result is shown in FIG. 18. FIG. 18 also shows the result obtained in FIG. 5. The broken line in FIG. 18 represents the correlation (PMOS) between the displacement amount and the variation in threshold value voltage.

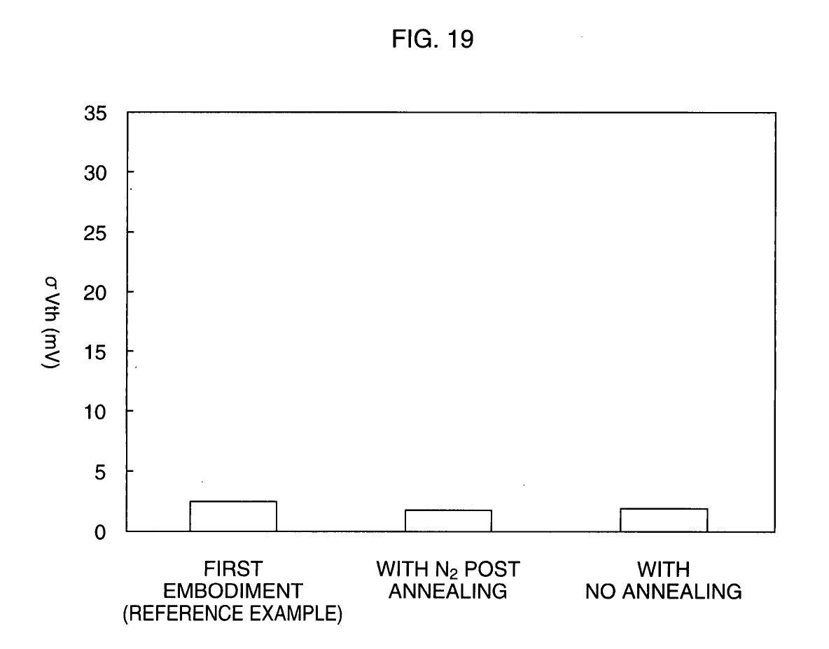

The inventors of the present invention further made three kinds of p-channel MOS transistors by a method according to the second embodiment, and measured variation (σᵥₜₕ) in threshold value voltage in these transistors. Note that in making the three kinds of p-channel MOS transistors, post-annealing was conducted at the same annealing temperature as that for the three kinds of n-channel MOS transistors produced for the measurement of trans-conductance (Gm) and gate voltage (Vg) that was made relating to the second embodiment. The result is shown in FIG. 19.

As shown in FIG. 19, the variation in threshold value voltage was also substantially equal to that in the reference example (first embodiment) when the post-annealing was conducted. This indicates that boron penetration is also suppressed when the post-annealing is conducted.

Incidentally, by measuring the displacement amount of Si atoms on the surface of a Si substrate toward a gate insulation film side or the inner side of the substrate after a gate insulation film is formed on the Si substrate, the performance of a semiconductor device having the gate insulation film can be estimated, prior to the completion of the semiconductor device, based on the displacement amount. Specifically, in an n-channel MOS transistor, a larger displacement amount toward the gate insulation film side can lead to such estimation that leak current and boron penetration are smaller. In a p-channel MOS transistor, a larger displacement amount toward the inner side of the substrate can lead to such estimation that gate leak current and boron penetration are smaller.

It is also possible to guarantee stability of a gate insulation film based on the displacement amount of Si atoms on the surface of a Si substrate toward a gate insulation film side or the inner side of the substrate.

It is also possible to guarantee stability of a apparatus in which a gate insulation film is formed, based on the displacement amount of Si atoms on the surface of a Si substrate toward a gate insulation film side or the inner side of the substrate.

According to the present invention, carrier mobility is improved owing to the displacement of Si atoms on a surface of a Si substrate. Therefore, it is possible to achieve sufficient carrier mobility even if nitrogen concentration near an interface between a gate insulation film and the Si substrate becomes high. Further, the increase in nitrogen concentration can further suppress boron penetration and can also reduce gate leak current.

The present embodiments are to be considered in all respects as illustrative and no restrictive, and all changes which come within the meaning and range of equivalency of the claims are therefore intended to be embraced therein. The invention may be embodied in other specific forms without departing from the spirit or essential characteristics thereof.

What is claimed is:

1. A semiconductor device comprising:
a silicon substrate;
a gate insulation film formed over said silicon substrate; and
a gate electrode formed over said gate insulation film,
silicon atoms on a surface of said silicon substrate being displaced toward said gate insulation film side.

2. The semiconductor device according to claim 1, wherein a conductive type of said surface of said silicon substrate is P-type below said gate insulation film.

3. The semiconductor device according to claim 1, wherein a displacement amount of said silicon atoms on said surface of said silicon substrate is 0.0075 nm or more.

4. The semiconductor device according to claim 3, wherein said displacement amount is 0.01 nm to 0.03 nm.

5. A semiconductor device comprising:
a silicon substrate;
a gate insulation film formed over said silicon substrate; and
a gate electrode formed over said gate insulation film,
silicon atoms on a surface of said silicon substrate in a region where a conductive type of said surface is P-type below said gate insulation film being displaced toward said gate insulation film side, and
silicon atoms on said surface in a region where said conductive type of said surface is N-type below said gate insulation film being displaced toward an inner side of said silicon substrate.

6. The semiconductor device according to claim 5, wherein
a displacement amount of said silicon atoms in said region where the conductive type of said surface is N-type is 0.01 nm to 0.03 nm, and
a displacement amount of said silicon atoms in said region where the conductive type of said surface is P-type is 0.01 nm or less.

7. The semiconductor device according to claim 1, wherein said gate insulation film comprises:
a silicon oxide film containing nitrogen and formed over said silicon substrate; and
a silicon nitride film or high dielectric constant film formed over said silicon oxide film.

8. The semiconductor device according to claim 1, wherein said gate insulation film comprises:
a silicon oxide film containing nitrogen and formed over said silicon substrate;
a high dielectric constant film formed over said silicon oxide film; and
a silicon nitride film formed over said high dielectric constant film.

9. A manufacturing method of a semiconductor device comprising the steps of:
forming a gate insulation film over a silicon substrate; and
forming a gate electrode over said gate insulation film,
said step of forming a gate insulation film including the steps of:
forming a silicon oxide film over said silicon substrate; and
introducing nitrogen into said silicon oxide film and displacing silicon atoms on a surface of said silicon substrate toward said gate insulation film side.

10. The method according to claim 9, wherein said step of introducing nitrogen and displacing silicon atoms comprises the step of conducting a first heat treatment to said silicon oxide film in an ammonia atmosphere or nitrogen monoxide atmosphere.

11. The method according to claim 9, wherein said gate insulation film is formed over a region where a conductive type of said surface of said silicon substrate is P-type.

12. A manufacturing method of a semiconductor device comprising the steps of:
forming a gate insulation film over a silicon substrate; and
forming a gate electrode over said gate insulation film,
said step of forming a gate insulation film including the steps of:
forming a silicon oxide film over said silicon substrate; and
introducing nitrogen into said silicon oxide film, displacing silicon atoms on a surface of said silicon substrate in a region where a conductive type of said surface is P-type below said gate insulation film toward said gate insulation film side, and displacing silicon atoms on said surface in a region where said conductive type of said surface is N-type below said gate insulation film toward an inner side of said silicon substrate.

13. The method according to claim 12, wherein said step of introducing nitrogen and displacing silicon atoms comprises the step of conducting a first heat treatment to said silicon oxide film in a ammonia atmosphere or nitrogen monoxide atmosphere in said region where the conductive type of said surface is P-type, and conducting a plasma nitridation treatment to said silicon oxide film in an ammonia atmosphere or nitrogen monoxide atmosphere in said region where the conductive type of said surface is N-type.

14. The method according to claim 10, wherein said first heat treatment is conducted at 775° C. or higher.

15. The method according to claim 9, wherein said step of forming a gate insulation film comprises the step of forming a silicon nitride film or high dielectric constant film over said silicon oxide film, after said step of introducing nitrogen and displacing silicon atoms.

16. The method according to claim 15, wherein said step of forming a gate insulation film comprises the step of conducting a second heat treatment to said silicon oxide film, to which nitrogen has been introduced, after said step of forming a silicon nitride film or high dielectric constant film.

17. The method according to claim 16, wherein said second heat treatment is conducted at a higher temperature than that at which said silicon nitride film or high dielectric constant film is formed.

18. The method according to claim 9, wherein said step of forming a gate insulation film comprises the steps of, after said step of introducing nitrogen and displacing silicon atoms:
forming a high dielectric constant film over said silicon oxide film;
conducting a second heat treatment to said silicon oxide film, to which nitrogen has been introduced; and
forming a silicon nitride film over said high dielectric constant film.

19. The method according to claim 16, wherein said second heat treatment is conducted in a nitrogen monoxide atmosphere.

20. The method according to claim 9, wherein said silicon oxide film is 1.5 nm or less in thickness.
